(19) United States
(12) Patent Application Publication
(10) Pub. No.: US 2026/0223281 A1
(43) Pub. Date: Jul. 30, 2026

(54) CIRCUIT BOARD

(71) Applicant: FANUC CORPORATION, Yamanashi (JP)

(72) Inventors: Yunosuke KANEKO, Yamanashi (JP); Nobuyuki OOTAKE, Yamanashi (JP)

(21) Appl. No.: 19/149,093

(22) PCT Filed: Jan. 31, 2023
(86) PCT No.: PCT/JP2023/003084

§ 371 Date: Jul. 18, 2025

(51) Int. Cl. H05K 1/02

(52) U.S. Cl. CPC H05K 1/0268

(57) ABSTRACT

The circuit board according to the present disclosure includes a board, an electronic circuit, an inspection portion, and a protective film. The electronic circuit is mounted on the board. The inspection portion is mounted on the board to be electrically separated from the electronic circuit. The inspection portion includes a plurality of conductive pads and a connection line for electrically connecting the conductive pads to each other. The protective film covers the inspection portion together with the electronic circuit.

### RELATED APPLICATIONS

The present application is a National Phase of International Application No. PCT/JP2023/003084 filed Jan. 31, 2023.

The present disclosure relates to a circuit board having a function of inspecting the presence or absence of a protective film.

### TECHNICAL FIELD

### Background Art

Today, as communication technology, sensor technology, and control technology evolve, circuit boards in which electronic components are mounted on printed wiring boards have become indispensable components. Circuit boards are required to have various properties depending on the environment in which the circuit boards are placed. For example, a circuit board placed inside a cutting machine is required to have cutting fluid resistance. As a technique for improving the cutting fluid resistance of the circuit board, so-called parylene coating, in which para-xylylene is adhered to the circuit board by vapor deposition, is known. The parylene coating film formed by parylene coating has excellent cutting fluid resistance, but is colorless and transparent, making it difficult to determine its presence. In order to make it possible to determine the presence or absence of a colorless, transparent parylene coating film, there is a known technology to make the parylene coating film have fluorescent properties (Patent Literature 1).

### CITATION LIST

### Patent Literature

Patent Literature 1: Japanese Unexamined Patent Application Publication No. 4-283223

### SUMMARY

### Problem to be Solved

However, to make the parylene coating film fluorescent, it is necessary to install a plasma generator or the like, which increases the facility cost. Therefore, it is desired to propose a technology to easily confirm whether or not a circuit board has a protective film such as a colorless, transparent parylene coating film.

### Solution to Problem

A circuit board according to the present disclosure comprises: a board; an electronic circuit mounted on the board; an inspection portion mounted to be electrically separated from the electronic circuit and including a plurality of conductive pads and a connection line electrically connecting the conductive pads to each other; and an insulating protective film covering the inspection portion together with the electronic circuit.

### BRIEF DESCRIPTION OF THE DRAWINGS

FIG. 1 is a perspective view showing an example of a circuit board according to the present embodiment.

FIG. 2 is a plan view of the circuit board in FIG. 1.

FIG. 3 is a cut end view taken along A-A′ in FIG. 2

FIG. 4 is a supplementary diagram for explaining a method of inspecting the presence or absence of a coating of a circuit board according to the present embodiment.

FIG. 5 is a plan view showing a first modification of the circuit board according to the present embodiment.

FIG. 6 is a plan view showing a second modification of the circuit board according to the present embodiment.

FIG. 7 is a plan view showing a third modification of the circuit board according to the present embodiment.

FIG. 8 is a plan view showing a fourth modification of the circuit board according to the present embodiment.

FIG. 9 is a perspective view showing a fifth modification of the circuit board according to the present embodiment.

FIG. 10 is a cut end view taken along B-B′ in FIG. 9

### DETAILED DESCRIPTION

Hereinafter, a circuit board according to the present embodiment will be described with reference to the drawings. In the following description, constituent elements having substantially the same function and configuration are denoted by the same reference numeral, and repetitive descriptions will be given only where necessary.

One feature of the circuit board according to the present embodiment is that it has a structure that makes it possible to inspect the presence or absence of a protective film of the circuit board. Typically, this structure is used in the manufacture of circuit boards to inspect whether a coating has been applied to the circuit board, allowing inspection for the presence or absence of a colorless, transparent parylene coating film, which is difficult for workers to visually confirm or difficult to extract by image processing based on a camera image. Typically, the circuit board according to the present embodiment is configured as follows.

In the present embodiment, terms are defined as follows.

Board: A plate-shaped member made of an insulating material. In the present embodiment, the insulating material may be a rigid material or a flexible material.

Printed wiring board: A board with a conductor pattern constituting at least a part of an electronic circuit printed on its front surface, back surface, inside, etc.

Printed circuit board: A printed wiring board to which circuit elements (electronic components) are soldered and which is operable as an electronic circuit.

Circuit board: A coated printed circuit board. In other words, a printed circuit board entirely covered with a parylene coating film (protective film).

Electronic circuit: A circuit mounted on a board in order to realize the original function of the circuit board according to the present embodiment.

Inspection portion: A structure mounted on a board to enable inspection of whether a printed circuit board is covered with a parylene coating film. The inspection portion is a structure uniquely provided in the circuit board according to the present embodiment, which is not directly related to the realization of the original function of the circuit board according to the present embodiment.

Note that, in the present embodiment, the printed wiring board is described as a so-called single-sided board consisting of two layers, an insulating layer and a conductive layer, in which a conductive pattern can be formed only on the front surface of the board, and in which an electronic circuit and an inspection portion are mounted on the front surface of the board. However, the printed wiring board may be a double-sided board consisting of three layers: conductive layer-insulating layer-conductive layer, or a multilayer board with at least three or more conductive layers. Alternatively, the electronic circuit and the inspection portion may be mounted using both surfaces of the board.

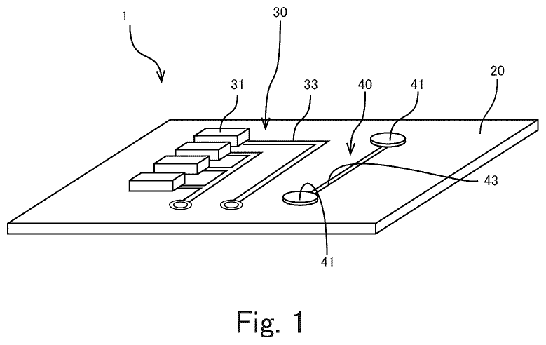

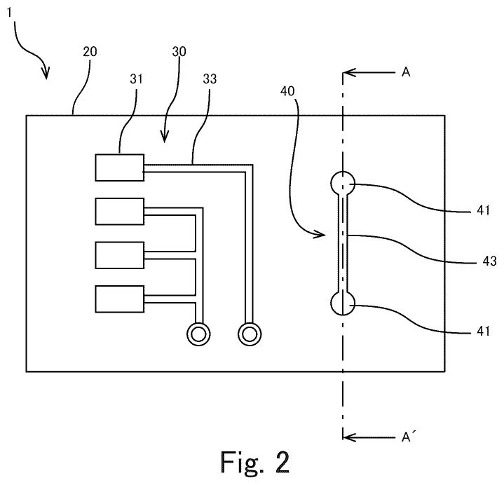

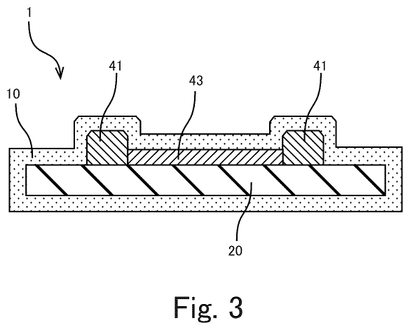

The configuration of the circuit board according to the present embodiment will be described below with reference to FIG. 1 to FIG. 3. FIG. 1 is a perspective view showing an example of the circuit board according to the present embodiment. FIG. 2 is a plan view of the circuit board in FIG. 1. FIG. 3 is a cut end view taken along A-A′ in FIG. 2

As shown in FIG. 1, FIG. 2, and FIG. 3, a circuit board 1 according to the present embodiment includes an insulating board 20, an electronic circuit 30 mounted on a front surface of the board 20, an inspection portion 40 mounted on the front surface of the board 20, and an insulating protective film 10 covering the inspection portion 40 together with the electronic circuit 30. The board 20, and the electronic circuit 30, and the inspection portion 40 mounted on the front surface of the board 20 are collectively referred to as a printed circuit board.

The insulating protective film 10 covers the entire surface (front surface, back surface, and side surface) of the printed circuit board. Typically, the insulating protective film 10 is realized by a colorless and transparent parylene coating film 10 also having cutting fluid resistance. The parylene coating film 10 is formed by depositing para-xylylene on the printed circuit board. However, the insulating protective film 10 is not limited to a parylene coating film, and may be, for example, another type of protective film having high transparency to visible light like a parylene coating film, or a type of protective film having low transparency to visible light which can be visually confirmed.

The electronic circuit 30 includes circuit elements 31 and a conductive connection line 33 for electrically connecting the circuit elements 31 to each other. For example, the circuit elements 31 include an integrated circuit, a sensor, a resistor, an inductor, a capacitor, and the like. Typically, the connection line 33 is realized by a conductor pattern formed on the front surface of the board 20. The connection line 33 may include a through hole formed in the board 20, or may be realized by an independent conductive member such as a lead wire.

The inspection portion 40 is used for inspecting the presence or absence of the parylene coating film 10. It is composed of two conductive pads 41 and a conductive connection line 43 for connecting the two pads 41. Typically, the two pads 41 have a circular shape and are realized by independent conductive members. The connection line 43 is a single straight line and is realized by a conductor pattern on the front surface of the board 20. That is, the inspection portion 40 is realized by soldering two pads 41 to both ends of a linear conductor pattern as the connection line 43 formed on the front surface of the board 20.

The inspection portion 40 is mounted to be electrically separated from the electronic circuit 30. Electrically separated means that at least the structures are not in physical contact with each other. Of course, the term “electrically separated” may include a state in which the structures do not exert an electrical influence, such as electromagnetic coupling or capacitive coupling, on each other. For example, the inspection portion 40 is mounted on the board 20 in such a manner that the two pads 41 and the connection line 43 constituting the inspection portion 40 are not in physical contact with the connection line 33 constituting the electronic circuit 30. Preferably, the inspection portion 40 is mounted in a region on the front surface of the board 20 where the mounting density of the circuit elements 31 and connection line 33 constituting the electronic circuit 30 is low.

As shown in FIG. 3, it is desirable that the two pads 41 are thicker than the connection line 43. Accordingly, a step can be formed between the connection line 43 and the pads 41, and the contact area of the parylene coating film 10 with the printed circuit board can be increased as compared with the case where the pads 41 have the same thickness as the connection line 43. As will be described later, increasing the contact area of the parylene coating film 10 with the printed circuit board contributes to improving the adhesion of the parylene coating film 10 to the printed circuit board.

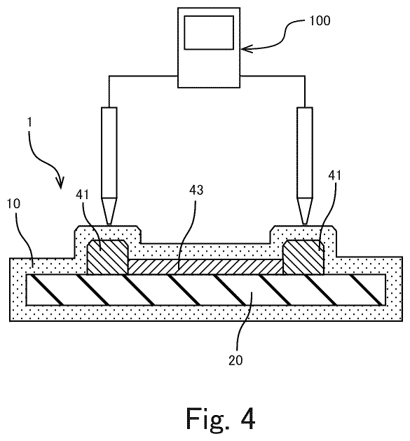

A method for inspecting the presence or absence of the parylene coating film 10 of the circuit board 1 according to the present embodiment will be described below with reference to FIG. 4. FIG. 4 is a supplementary diagram for explaining the method for inspecting the presence or absence of the parylene coating film 10 of the circuit board 1 according to the present embodiment. The presence or absence of the parylene coating film 10 of the circuit board 1 according to the present embodiment can be inspected using a continuity checker 100. The continuity checker 100 is a device having two probes and capable of judging the conductive/non-conductive state between two points to which the two probes are applied respectively.

As shown in FIG. 4, in order to inspect the presence or absence of the parylene coating film 10 of the circuit board 1 according to the present embodiment, the two probes of the continuity checker 100 are brought into contact with positions corresponding to the two pads 41 of the inspection portion 40, respectively. When the two pads 41 are covered with the parylene coating film 10, the two probes are not electrically connected to the two pads 41 respectively and the state between the two probes is non-conductive because the parylene coating film 10 is insulating. When the two pads 41 are not covered with the parylene coating film 10, the two probes come into direct contact with the two pads 41 respectively so that the state between the two probes is conductive through the inspection portion 40.

Note that the parylene coating film 10 of the circuit board 1 according to the present embodiment is formed by vapor deposition. In the coating by vapor deposition, the entire printed circuit board placed in a vapor deposition chamber can be coated uniformly, so that it never happens that only a part of the printed circuit board is covered with the parylene coating film 10. In other words, the fact that the two pads 41 are covered with the parylene coating film 10 means that the entire printed circuit board is covered with the parylene coating film 10. Similarly, the fact that the two pads 41 are not covered with the parylene coating film 10 means that the entire printed circuit board is not covered with the parylene coating film 10.

Therefore, the presence or absence of the parylene coating film 10 of the circuit board 1, in other words, whether or not vapor deposition coating has been performed on the printed circuit board can be inspected based on the result of determining the conductive/non-conductive state between the two probes when the two probes of the continuity checker 100 are brought into contact with the positions corresponding to the two pads 41 of the inspection portion 40, respectively.

Since the circuit board 1 according to the present embodiment has the inspection portion 40, the presence or absence of the parylene coating film 10 of the circuit board 1, in other words, whether or not vapor deposition coating has been performed on the printed circuit board can be easily inspected only by bringing the two probes of the continuity checker 100 into contact with the positions of the two pads 41 of the inspection portion 40. The fact that the circuit board 1 has a structure capable of inspecting whether or not coating has been performed on itself contributes to the improvement of the reliability of the circuit board 1.

An electronic circuit 30 for realizing the original function of the circuit board 1 is also mounted on the board 20 on which the structure constituting the inspection portion 40 is mounted. However, since the inspection portion 40 is mounted at a position electrically separated from the electronic circuit 30, the mounting of the inspection portion 40 does not hinder the original function of the electronic circuit 30. In addition, even if the surface of the parylene coating film 10 is scratched by the probes coming into contact with the positions of the pads 41 of the inspection portion 40 and the cutting fluid enters from the scratch, the cutting fluid can be prevented from reaching the electronic circuit 30 or the time until the cutting fluid reaches the electronic circuit 30 can be delayed, preventing the electronic circuit 30 from developing corrosion.

Further, by mounting not only the electronic circuit 30 for realizing the original function of the circuit board 1 but also the inspection portion 40 on the board 20, the unevenness of the front surface of the printed circuit board increases, so that the contact area where the parylene coating film 10 comes into contact with the printed circuit board can be increased, and the adhesion of the parylene coating film 10 to the printed circuit board can be improved. The peeling of the parylene coating film 10 tends to occur on a flat surface having low contact area, and once the peeling occurs, the peeling may spread to an uneven portion having high contact area. The inspection portion 40 is mounted in a region where the mounting density of the circuit elements 31 and connection line 33 constituting the electronic circuit 30 is low on the front surface of the board 20, that is, on a flat surface where the contact area with the parylene coating film 10 is low. Therefore, the flat surface of the printed circuit board where the parylene coating film 10 is likely to be peeled off can be reduced, and the possibility that the parylene coating film 10 of the circuit board 1 is peeled off can be suitably reduced.

The inspection portion 40 can be formed by soldering two conductive pads 41 to a conductor pattern as the connection line 43 provided on the front surface of the board 20. The conductor pattern constituting the inspection portion 40 can be formed by the same process as the conductor pattern constituting the electronic circuit 30. Further, the process of soldering the two pads 41 to the conductor pattern constituting the inspection portion 40 can be easily added to the process of soldering the electronic components constituting the electronic circuit 30 to the conductor pattern constituting the electronic circuit 30. Therefore, it is possible to suppress an increase in cost due to additional mounting of the inspection portion 40 on the board 20.

In order to inspect the presence or absence of the parylene coating film 10, the two probes of the continuity checker 100 may be brought into contact with the two pads 41 provided at predetermined positions of the circuit board 1, respectively. Therefore, the inspection can be performed by a robot or the like, so that the process of inspecting the presence or absence of the parylene coating film 10 can be easily incorporated into the manufacturing process of the circuit board 1. In addition, only a continuity checker 100 is needed to inspect the presence or absence of the parylene coating film 10, which reduces the installation cost as compared with the case where a plasma generator is used. Further, since there is no need to identify the coating film itself to be inspected, the present embodiment can be applied to the inspection of the presence or absence of the colorless and transparent parylene coating film 10, which is difficult to be visually confirmed by workers or extracted by image processing based on a camera image.

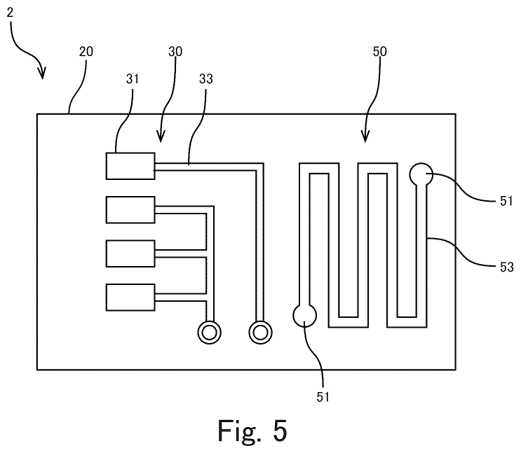

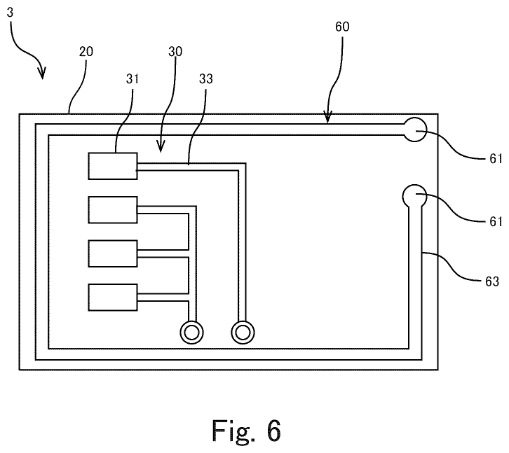

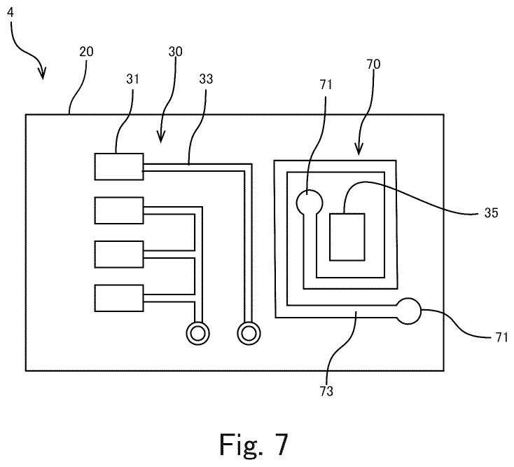

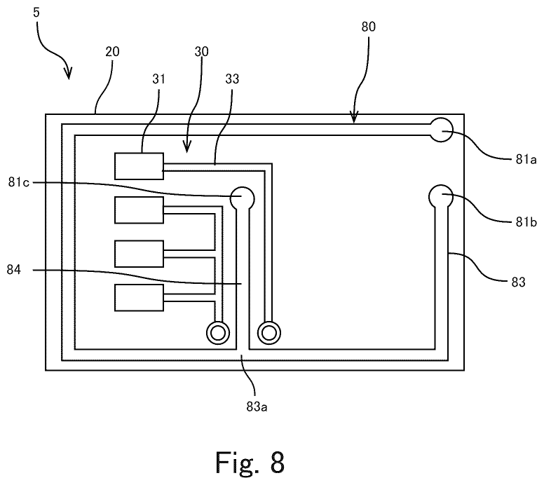

In the circuit board 1 according to the present embodiment, the connection line 43 of the inspection portion 40 has a linear shape. However, the shape of the inspection portion is not limited to this. A modification of the inspection portion will be described with reference to FIG. 5, FIG. 6, FIG. 7, and FIG. 8.

As shown in FIG. 5, a connection line 53 constituting an inspection portion 50 of a circuit board 2 according to a first modification has a zigzag shape in which the connection line 53 is alternately folded many times in opposite directions, and conductive pads 51 are connected to both ends of the connection line 53. This shape is also referred to as a wave form having rectangular peaks and valleys.

As shown in FIG. 6, a connection line 63 of an inspection portion 60 of a circuit board 3 according to a second modification is configured to have a peripheral shape along the outer periphery of the board 20. Conductive pads 61 are connected to both ends of the connection line 63. The peripheral shape along the outer periphery of the board 20 is not limited to the overall shape of the outer periphery of the board 20, but includes the shape of a part of the outer periphery of the board 20. As described above, the inspection portion makes it possible to inspect the presence or absence of the parylene coating film 10 and also contributes to the improvement of the adhesion of the parylene coating film 10 to the printed circuit board. As shown in FIG. 5 and FIG. 6, the adhesion of the parylene coating film 10 to the printed circuit board can be further improved by increasing the length of the connection line 53, 63 of the inspection portion 50, 60 to increase the contact area of the parylene coating film 10 with the printed circuit board.

As shown in FIG. 7, a connection line 73 constituting a inspection portion 70 of a circuit board 4 according to a third modification has a shape surrounding the important circuit element 35 of the electronic circuit 30. Conductive pads 71 are connected to both ends of the connection line 73, respectively. The conductive pads 71 are mounted on opposite sides of the important circuit element 35. The important circuit element 35 is, for example, an encoder circuit, an angle calculation processing circuit, and the like. Specifically, the connection line 73 has a spiral shape, and the inspection portion 70 is mounted at a position where the important circuit element 35 is placed at the center of the spiral. As described above, the adhesion of the parylene coating film to the printed circuit board can be made stronger at the mounting position of the inspection portion and its surrounding region. By using this and mounting the inspection portion 70 so as to surround the important circuit element 35 of the electronic circuit 30, the adhesion of the parylene coating film 10 at the mounting position of the important circuit element 35 can be improved, and the possibility of corrosion of the important circuit element 35 due to peeling of the parylene coating film 10 can be reduced.

As shown in FIG. 8, another conductive pad 81c is mounted along with conductive pads 81a and 81b on a circuit board 5 according to a fourth modification. A branch line 84 branches off at an arbitrary branch point 83a from the connection line 83, which connects the pads 81a and 81b, and connects the other pad 81c to the pads 81a and 81b. By allowing the connection line 83 to branch in this way, the degree of freedom in mounting the connection line 83 is improved, and the connection line can be mounted in a narrow region where the connection line cannot be folded.

In the circuit board 1 according to the present embodiment, the inspection portion 40 is configured by soldering two conductive pads 41 to a conductor pattern as the connection line 43 formed on the front surface of the board 20. However, the configuration of the inspection portion is not limited to this.

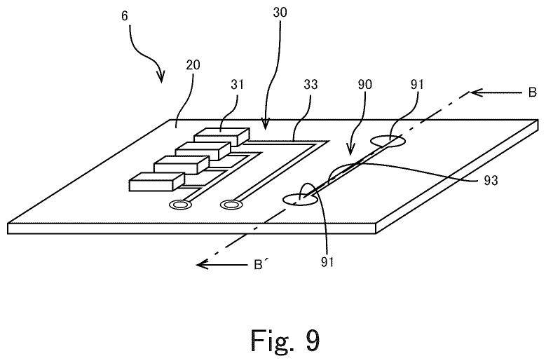

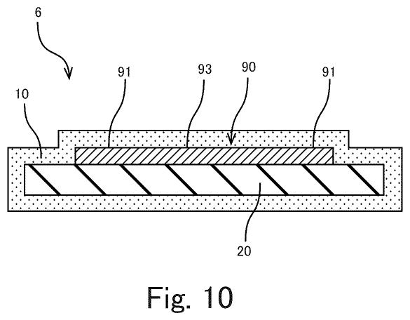

As shown in FIG. 9 and FIG. 10, in an inspection portion 90 of a circuit board 6 according to a fifth modification, two pads 91 and a connection line 93, which connects the two pads 91, are integrally formed by the conductor pattern on the front surface of the board 20. Thus, there is no need to prepare two pads 41 which are independent members, and the inspection portion 90 can be formed by the same process as the conductor pattern constituting the electronic circuit 30, so that the cost of additionally mounting the inspection portion 90 on the board 20 can be further suppressed.

Although not shown, the two pads 41 constituting the inspection portion 40 may be formed by a conductor pattern, and the connection line 43, which connects the two pads 41, may be realized by an independent member such as a lead wire.

In the present embodiment, the parylene coating film 10 of the circuit board 1 is formed by vapor deposition coating; therefore, it can be considered that the entire printed circuit board is covered with the parylene coating film when the two pads 41, which constitute the inspection portion 40 of the circuit board 1, are covered with the parylene coating film, and it can be considered that the entire printed circuit board is not covered with the parylene coating film when the two pads 41 are not covered with the parylene coating film. However, the method of coating the printed circuit board is not limited to vapor deposition, and it is possible to coat only a part of the printed circuit board. The present embodiment can also be applied to the inspection of the presence or absence of a protective film partially covering the printed circuit board. In this case, the inspection portion may be mounted in a region covered with the protective film of the printed circuit board, and the electronic circuit may not necessarily be mounted in that region.

In the present embodiment, a printed circuit board in which the electronic circuit 30 and the inspection portion 40 are mounted on the insulating board 20 is defined as a printed circuit board, and a printed circuit board covered with the parylene coating film 10 having cutting fluid resistance is defined as the circuit board 1. However, the printed circuit board may be defined to include other protective films that may be applied to conventional rigid or flexible boards, such as solder resist to prevent solder from adhering to unwanted portions and to protect the conductor pattern from dust, heat, moisture, and the like.

In the present embodiment, the inspection portion 40 has two pads 41. However, the inspection portion 40 may be configured to have three or more pads 41. For example, an inspection portion may be configured by three conductive pads and a conductive connection line connecting the three pads, and the presence or absence of the parylene coating film 10 may be inspected by a continuity checker in accordance with three combinations of two of the three pads. Of course, since the inspection is performed three times, the inspection accuracy can be improved. From a similar perspective, the circuit board 1 may have a plurality of inspection portions 40.

In the present embodiment, the inspection portion is described as being configured only on the front surface of the board, but it may be configured on both surfaces of the board. In this case, a first inspection portion may be mounted on the front surface of the board and a second inspection portion may be mounted on the back surface of the board. Of course, a configuration may be adopted in which the connection lines constituting the inspection portion is mounted on the front surface and the back surface of the board, these are electrically connected through a through hole, and a plurality of pads constituting the inspection portion are mounted on one surface or both surfaces of the board. By providing the inspection portion on both surfaces of the board, the presence or absence of the protective film on both surfaces of the circuit board can be inspected and the possibility of peeling of the protective film on both surfaces can be reduced.

The following appendixes are further disclosed with respect to the present embodiment and modifications.

### (Appendix 1)

A circuit board 1 comprises: a board 20; an electronic circuit 30 mounted on the board 20; an inspection portion 40 mounted to be electrically separated from the electronic circuit 30 and including a plurality of conductive pads 41 and a connection line 43 electrically connecting the conductive pads 41 to each other; and an insulating protective film 10 covering the inspection portion 40 together with the electronic circuit 30.

### (Appendix 2)

The connection line 43 of Appendix 1 is a single straight line.

### (Appendix 3)

The inspection portion 40 of Appendix 1 further includes another conductive pad 81c mounted on the board 20 and a branch line 84 branching off from the connection line 83 to connect the another conductive pad 81c to the conductive pads 81a and 81b.

### (Appendix 4)

The connection line 43 of Appendix 1 has a zigzag shape in which the connection line 43 is alternately folded in opposite directions.

### (Appendix 5)

The connection line 43 of Appendix 1 has a shape surrounding a circuit element of the electronic circuit 30.

### (Appendix 6)

The connection line 43 of Appendix 1 has a peripheral shape along a periphery of the board 20.

While embodiments of the present disclosure have been described in detail, the present disclosure is not limited to the individual embodiments described above. These embodiments may be subjected to various additions, substitutions, modifications, partial deletions, etc., without departing from the gist of the invention or the idea and spirit of the present invention as derived from the contents described in the claims and their equivalents. For example, in the above-described embodiments, the order of the operations and the order of the processes are shown as examples, and the present invention is not limited thereto. The same applies to the case where numerical values or formulas are used in the description of the above-described embodiments.

1. A circuit board comprising:
a board;
an electronic circuit mounted on the board;
an inspection portion mounted to be electrically separated from the electronic circuit and including a plurality of conductive pads and a connection line electrically connecting the conductive pads to each other; and
an insulating protective film covering the inspection portion together with the electronic circuit.

2. The circuit board according to claim 1, wherein the connection line is a single straight line.

3. The circuit board according to claim 1, wherein
the detection unit further includes:
another conductive pad mounted on the board; and
a branch line branching off from the connection line to connect the another conductive pad to the conductive pads.

4. The circuit board according to claim 1, wherein the connection line has a zigzag shape in which the connection line is alternately folded in opposite directions.

5. The circuit board according to claim 1, wherein the connection line has a shape surrounding a circuit element of the electronic circuit.

6. The circuit board according to claim 1, wherein the connection line has a periphery shape along a periphery of the board.
